(19) United States
(12) Patent Application Publication
(10) Pub. No.: US 2007/0062910 A1
(43) Pub. Date: Mar. 22, 2007

(54) Complex CMP process and fabricating methods of STI structure and interconnect structure

(76) Inventors: Ming-Hsin Yeh, Jhongli City (TW); Cheng-Chuan Lee, Fenyuan Township (TW); Ming-Te Chen, Shengang Township (TW); Yi-Ching Wu, Yong-an Township (TW); Chin-Hsiang Hsiao, Hsinchu City (TW)

Correspondence Address: J C PATENTS, INC., 4 VENTURE, SUITE 250, IRVINE, CA, 92618, US

(21) Appl. No.: 11/233,585

(22) Filed: Sep. 22, 2005

(51) Int. Cl. C03C 15/00; H01L 21/461; B44C 1/22; C23F 1/00; H01L 21/302

(52) U.S. Cl. 216/88; 438/692; 216/41

(57) ABSTRACT

A complex CMP process is described. A target film is coarsely polished using a first polishing platen in a first CMP machine. The remaining target film is then fine polished using successively a second polishing platen and a third polishing platen in a second CMP machine that is different from the first CMP machine.

### BACKGROUND OF THE INVENTION

1. Field of the Invention

The present invention relates to a chemical mechanical polishing (CMP) process and fabricating methods of semiconductor structures. More particularly, the present invention relates to a complex CMP process and fabricating methods of a shallow trench isolation (STI) structure and an interconnect structure.

2. Description of the Related Art

In a semiconductor process, surface planarization is a very important issue for high-resolution lithography, because a rugged surface causes significant light scattering in the exposure step making the pattern transfer inaccurate. Since the CMP technology is the only solution for global planarization in VLSI circuits and even ULSI circuits, most of wafer-surface planarization processes are currently done through CMP.

Among various CMP machines, the fixed abrasive CMP (FACMP) machine is used more frequently now. A FACMP machine includes at least two polishing platens, while a wafer with a film to be polished thereon is first placed, by using a robot, on the platen having coarser abrasive thereon for coarse polishing, and then on the other platen having finer abrasive thereon for fine polishing. Though the planarity achieved by using the FACMP machine is higher, the polishing rate of the FACMP machine, which is merely about 8 wafers per hour, is lower than that of an ordinary non-fixed abrasive CMP machine. In addition, because the FACMP machine itself and the consumptive materials used therein are both expensive, the manufacturing process costs too much.

### SUMMARY OF THE INVENTION

In view of the foregoing, one object of this invention is to provide a complex CMP process, which may utilize the combination of a FACMP machine and a non-fixed abrasive CMP machine for planarization to improve the polishing efficiency and thereby increase the throughput, as well as to lower the manufacturing cost.

Another object of this invention is to provide a method for fabricating an STI structure, which may use a FACMP machine together with a non-fixed abrasive CMP machine to planarize the STI insulating film for improving the polishing efficiency and the throughput of the process.

Still another object of this invention is to provide a method for fabricating an interconnect structure, which may use a FACMP machine together with a non-fixed abrasive CMP machine to planarize the conductive film for higher polishing efficiency and more throughput.

The complex CMP process of this invention is described as follows. A target film is coarsely polished using a first polishing platen in a first CMP machine. The remaining target film is then fine polished using successively a second polishing platen and a third polishing platen in a second CMP machine that is different from the first CMP machine.

In one embodiment of this invention, the first CMP machine is a non-fixed abrasive CMP machine, while the second CMP machine is a FACMP machine. The polishing rate to the target film on the first polishing platen is preferably higher than that on the second or third polishing platen, and the polishing rate on the second polishing platen may be substantially the same as that on the third polishing platen.

The method for fabricating an STI structure of this invention is described as follows. A semiconductor substrate is provided, and then a patterned hard mask layer is formed thereon. A trench is formed in the substrate using the patterned hard mask layer as an etching mask. An insulating film is then formed on the patterned hard mask layer and in the trench. Thereafter, the insulating film is coarsely polished using a first polishing platen in a first CMP machine. The remaining insulating film is then fine polished using successively a second polishing platen and a third polishing platen in a second CMP machine that is different from the first CMP machine to completely remove the insulating film on the hard mask layer. The patterned hard mask layer is then removed.

In one preferred embodiment of the above method, the first and the second CMP machines are respectively a non-fixed abrasive CMP machine and a FACMP machine. The polishing rate to the insulating film on the first polishing platen is preferably higher than that on the second or third polishing platen, and the polishing rate on the second polishing platen may be substantially the same as that on the third polishing platen. In addition, the abrasive used in the first CMP machine may include silicon dioxide (SiO₂) particles, while that used in the second CMP machine may include cerium dioxide (CeO₂) particles. The material of the hard mask layer may be silicon nitride (SiN).

The method for fabricating an interconnect structure of this invention is described as follows. A substrate is provided, and then a dielectric layer is formed thereon. An opening is formed in the dielectric layer, and then a conductive film is formed on the dielectric layer and in the opening. Thereafter, the conductive film is coarsely polished using a first polishing platen in a first CMP machine. The remaining conductive film is then fine polished using successively a second polishing platen and a third polishing platen in a second CMP machine different from the first CMP machine to completely remove the conductive film on the dielectric layer.

In one preferred embodiment of the above method, the first and the second CMP machines are respectively a non-fixed abrasive CMP machine and a FACMP machine. The polishing rate to the conductive film on the first polishing platen is preferably higher than that on the second or third polishing platen, and the polishing rate on the second polishing platen may be substantially the same as that on the third polishing platen. In addition, the conductive film may be a metal film, such as a copper film.

Accordingly, in a preferred embodiment of the complex CMP process of this invention, a non-fixed abrasive CMP machine is first used to coarsely polish the target film in high speed, and then a FACMP machine is used to fine polish the remaining target film with two polishing platens having substantially the same polishing rate. Therefore, not only a good planarity can be made via the fine polishing in the FACMP machine, but also the polishing time can be reduced to increase the throughput. Meanwhile, since the non-fixed abrasive CMP machine itself and the consumptive materials used therein are both cheaper, the manufacturing cost can be lowered.

It is to be understood that both the foregoing general description and the following detailed description are exemplary, and are intended to provide further explanation of the invention as claimed.

### BRIEF DESCRIPTION OF THE DRAWINGS

FIG. 1 illustrates the flow chart of a complex CMP process according to a preferred embodiment of this invention.

FIGS. 2A-2E illustrate a process flow of fabricating an STI structure according to the preferred embodiment of this invention in a cross-sectional view.

FIGS. 3A-3D illustrate a process flow of fabricating an interconnect structure according to the preferred embodiment of this invention in a cross-sectional view.

### DESCRIPTION OF THE PREFERRED EMBODIMENTS

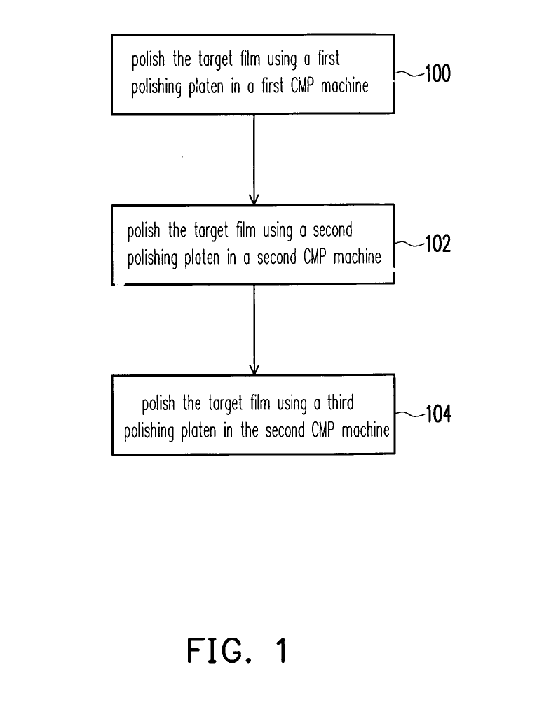

FIG. 1 illustrates the flow chart of a complex CMP process according to the preferred embodiment of this invention. In step 100, the target film, i.e., the film to be planarized, is coarsely polished using a first polishing platen in a first CMP machine that may be a non-fixed abrasive CMP machine, wherein the first polishing platen may represent one or multiple polishing platens in the first CMP machine. Specifically, in consideration of the wafer transfer mechanism in the first CMP machine, the target film can be polished using more than one polishing platens successively for improving the polishing efficiency of multiple wafers. The non-fixed abrasive CMP machine is suitable for coarse polishing in high speed, and the CMP machine itself and the consumptive materials, especially the abrasive, used therein are both cheaper so that the manufacturing cost can be lowered.

Next, the substrate having the coarsely polished target film thereon is taken out from the first CMP machine and then loaded into a second CMP machine. The type of the second CMP machine is different from that of the first CMP machine, and is possibly a FACMP machine that has multiple polishing platens, for example, 4 polishing platens. In step 102, the remaining target film is fine polished first using a second polishing platen in the second CMP machine. The polishing rate to the target film on the second polishing platen is lower than that on the first polishing platen in the first CMP machine, but the surface planarity of the remaining target film is improved with the polishing step 102.

Subsequently, in step 104, the substrate is placed on a third polishing platen in the same second CMP machine, and then the remaining target film is polished using the third polishing platen. The polishing rates on the second and third polishing platens are substantially the same, which means their difference is within a small range.

It is particularly noted that since the requirement in planarity in the coarse polishing step 100 is lower, a non-fixed abrasive CMP machine having a much higher polishing rate and costing less is used to increase the polishing efficiency and lower the manufacturing cost. Thereafter, a FACMP machine having multiple polishing platens is used to perform the fine polishing steps 102 and 104, wherein each wafer is polished successively on a second polishing platen and a third polishing platen that has substantially the same polishing rate.

The reasons to polish one wafer successively on two polishing platens of the same type includes that the polishing efficiency of multiple wafers can be improved as considering the wafer transfer mechanism in the CMP machine. More specifically, the second and the third two polishing platens can be rotated at the same time, so that when a wafer is being polished using the third polishing platen, another wafer can be polished using the second polishing platen that was just used to polish the wafer. Therefore, not only the planarity is good due to the fine polishing in the FACMP machine, but also the polishing time is reduced to increase the throughput of the process. In the following embodiments of this invention, the above complex CMP process is applied to an STI process and an interconnect process, respectively.

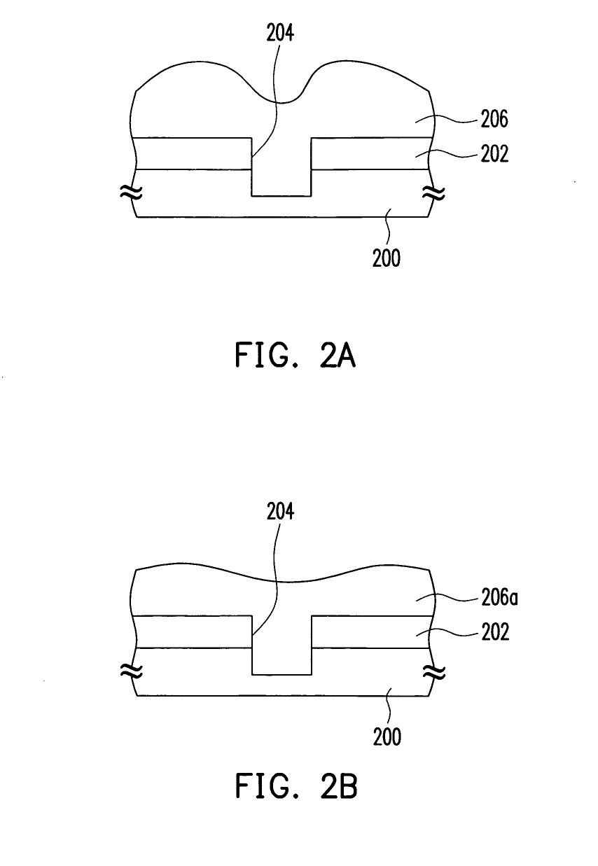

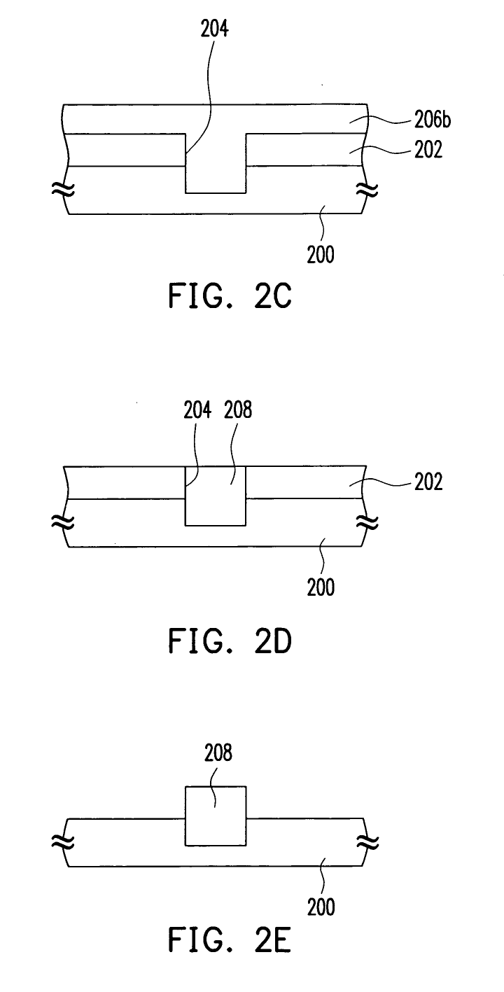

FIGS. 2A-2E illustrate a process flow of fabricating an STI structure according to the preferred embodiment of this invention in a cross-sectional view. Referring to FIG. 2A, a substrate 200 is provided, formed with a patterned hard mask layer 202 thereon and a trench 204 therein defined by the patterned hard mask layer 202. An insulating film 206, such as a silicon oxide film, is formed on the patterned hard mask layer 202 and in the trench 204. The material of the hard mask layer 202 is SiN, for example.

Referring to FIG. 2B, the insulating film 206 is coarsely polished in high speed using a first polishing platen in a first CMP machine to remove the a portion of the insulating film 206 to form a smoother insulating film 206a. The first CMP machine is preferably a non-fixed abrasive CMP machine that may include one or more polishing platens. The abrasive used may be SiO₂ particles. The polishing rate to the insulating film 206 on the first polishing platen is 3500 Å/min, for example.

Referring to FIG. 2C, the wafer with the insulating film 206a thereon is taken out from the first CMP machine and then loaded into a second CMP machine, which is different form the first CMP machine, for fine polishing. The insulating film 206a is fine polished using a polishing platen in the second CMP machine to form a smoother and thinner insulating film 206b. The second CMP machine is preferably a FACMP machine, which has multiple polishing platens, for example, 4 polishing platens.

Referring to FIG. 2D, the insulating film 206b is further fine polished using another polishing platen in the same second CMP machine, so as to completely remove the insulating film 206b on the patterned hard mask layer 202 to form an STI structure 208. The polishing rates to the insulating film 206a/b on the two polishing platens in the second CMP machine are both lower than that on the first polishing platen in the first CMP machine, but are substantially the same as each other, which means that their difference is within a small range.

The abrasive used in the second CMP machine may be CeO₂ particles, and the polishing rate usually ranges from 50 Å/min to 1500 Å/min, preferably from 200Å/min to 800 Å/min. The CeO₂ abrasive has a higher polishing selectivity to an insulating material as compared with the SiO₂ abrasive, and can make a surface non-uniformity as low as 3%, which is lower than the non-uniformity of 6% generally made by the SiO₂ abrasive. Then, the patterned hard mask layer 202 is removed, as shown in FIG. 2E.

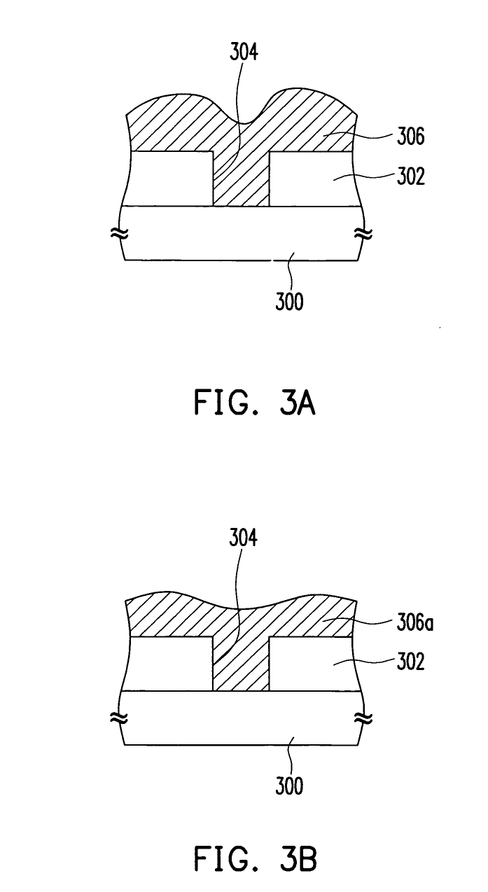

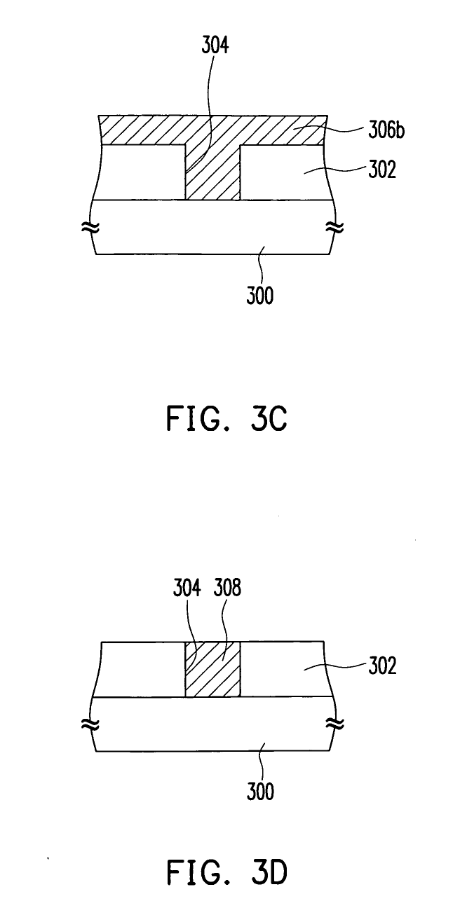

FIGS. 3A-3D illustrate a process flow of fabricating an interconnect structure according to the preferred embodiment of this invention in a cross-sectional view. In the fabricating process, the two types of CMP machines as mentioned above may be used respectively as the first and the second CMP machines.

Referring to FIG. 3A, a substrate 300 is provided, a dielectric layer 302 is formed on the substrate 300, an opening 304 is formed in the dielectric layer 302, and then a conductive film 306 is formed on the dielectric layer 302 and in the opening 304, wherein the conductive film 306 may be a metal film, such as a copper (Cu) film.

Referring to FIG. 3B, the conductive film 306 is coarsely polished in high speed using a first polishing platen in a first CMP machine to remove a portion of the conductive film 306 to form a smoother conductive film 306a. Thereafter, as shown in FIG. 3C, the wafer with the conductive film 306a thereon is taken out from the first CMP machine and then loaded into a second CMP machine. The conductive film 306a is then fine polished using a polishing platen in the second CMP machine to form a smoother and thinner conductive film 306b. Subsequently, as shown in FIG. 3D, the conductive film 306b is further fine polished using another polishing platen in the same second CMP machine, so as to completely remove the conductive film 306b on the dielectric layer 302 to form an interconnect structure 308.

As mentioned above, in the preferred embodiment of this invention, a non-fixed abrasive CMP machine that costs less is first used to coarsely polish the target film in high speed, and then a FACMP machine is used to fine polish the remaining target film. Therefore, not only the planarity is good due to the fine polishing, but also the polishing time can be reduced to increase the throughput of the CMP process up to, for example, 18 wafers per hour. Meanwhile, since the non-fixed abrasive CMP machine itself and the consumptive materials used therein are both cheaper, the manufacturing cost can be lowered at the same time.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

1. A complex chemical mechanical polishing (CMP) process, comprising:
coarsely polishing a target film on a substrate using a first polishing platen in a first CMP machine that comprises a non-fixed abrasive CMP machine; and
fine polishing the remaining target film in a second CMP machine that comprises a fixed abrasive CMP (FACMP) machine and includes a second polishing platen and a third polishing platen, comprising
polishing the remaining target film using the second polishing platen; and
polishing the remaining target film using the third polishing platen,
wherein a polishing rate to the target film on the second polishing platen is substantially the same as a polishing rate to the target film on the third polishing platen, and when the third polishing platen is being used to polish the target film on the substrate, the second polishing platen is used to polish the target film on another substrate.

2-3. (canceled)

4. The complex CMP process of claim 1, wherein a polishing rate to the target film on the first polishing platen in the first CMP machine is higher than a polishing rate on the second or third polishing platen in the second CMP machine.

5. (canceled)

6. A method for fabricating a shallow trench isolation (STI) structure, comprising:
providing a semiconductor substrate;
forming a patterned hard mask layer on the substrate;
forming a trench in the substrate by using the patterned hard mask layer as an etching mask;
forming an insulating film on the patterned hard mask layer and in the trench;
coarsely polishing the insulating film using a first polishing platen in a first CMP machine that comprises a non-fixed abrasive CMP machine;
fine polishing the remaining insulating film in a second CMP machine that comprises a fixed abrasive CMP (FACMP) machine and includes a second and a third polishing platens, comprising polishing the remaining insulating film using the second polishing platen and then polishing the remaining insulating film using the third polishing platen; and
removing the patterned hard mask layer,
wherein a polishing rate to the insulating film on the second polishing platen is substantially the same as a polishing rate to the insulating film on the third polishing platen, and when the third polishing platen is being used to polish the insulating film on the substrate, the second polishing platen is used to polish the insulating film on another substrate.

7-8. (canceled)

9. The method of claim 6, wherein a polishing rate to the insulating film on the first polishing platen in the first CMP machine is higher than a polishing rate on the second or third polishing platen in the second CMP machine.

10. (canceled)

11. The method of claim 6, wherein the first CMP machine uses an abrasive comprising SiO₂ particles, and the second CMP machine uses an abrasive comprising CeO₂ particles.

12. The method of claim 6, wherein the hard mask layer comprises silicon nitride.

13. A method for forming an interconnect structure, comprising: providing a substrate;
forming a dielectric layer on the substrate;
forming an opening in the dielectric layer;
forming a conductive film in the opening and on the dielectric layer,
coarsely polishing the conductive film using a first polishing platen in a first CMP machine that comprises a non-fixed abrasive CMP machine: and
fine polishing the remaining conductive film in a second CMP machine that comprises a fixed abrasive CMP (FACMP) machine and includes a second polishing platen and a third polishing platen, comprising
polishing the remaining conductive film using the second polishing platen; and
polishing the remaining conductive film using the third polishing platen,
wherein a polishing rate to the conductive film on the second polishing platen is substantially the same as a polishing rate to the conductive film on the third polishing platen, and when the third polishing platen is being used to polish the conductive film on the substrate, the second polishing platen is used to polish the conductive film on another substrate.

14-15. (canceled)

16. The method of claim 13, wherein a polishing rate to the conductive film on the first polishing platen in the first CMP machine is higher than a polishing rate on the second or third polishing platen in the second CMP machine.

17. (canceled)

18. The method of claim 13, wherein the conductive film comprises a metal film.

19. The method of claim 18, wherein the metal film comprises a copper film.
